(19) United States
(12) Patent Application Publication
(10) Pub. No.: US 2005/0128710 A1
(43) Pub. Date: Jun. 16, 2005

(54) Cooling system for electronic components

(76) Inventors: Abdlmonem H. BeiteImal, Los Altos, CA (US); Charndrakant D. Patel, Fremont, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/734,174

(22) Filed: Dec. 15, 2003

(51) Int. Cl. H05K 7/20

(52) U.S. Cl. 361/709; 361/711; 361/690; 165/80.3; 165/104.33

(57) ABSTRACT

A cooling system for an electronic system housing a heat-generating component. The cooling system generally includes a heat sink having a length and a width. The heat sink is configured to dissipate heat generated by the heat-generating component and has a base and a plurality of fins attached to the base. The plurality of fins are spaced apart from one another to have a relatively low height to width aspect ratio in the spacing between the plurality of fins. In addition, the heat-generating component has a length and a width, and at least one of the length and the width of the heat sink is substantially larger than at least one of an associated length and width of the heat-generating component.

### BACKGROUND OF THE INVENTION

Microprocessors have been developed to operate at faster speeds while occupying smaller spaces. In addition, electronic systems that house these microprocessors have also been developed to include a relatively dense configuration of microprocessors and other components to maximize processing power while minimizing the space required by the electronic systems. As the microprocessors and electronic systems become smaller and more dense, they also generate larger amounts of heat, thereby increasing the difficulty in maintaining the microprocessors and other components within desired temperature levels.

A heat sink is typically employed to dissipate the heat generated by the components contained in the electronic systems. More particularly, heat generated by the components is conducted to the heat sink where the heat is dissipated into air surrounding the components. The heat sink typically includes a configuration that enhances heat dissipation into the surrounding air. One heat sink configuration includes protruding fins that increase the surface area over which heat is dissipated from the heat sink to the surrounding air. Heat is typically dissipated into the surrounding air through convection, which may be enhanced through use of fans to increase air circulation over the heat sink fins.

Heat transfer within the heat sink has also been enhanced through use of heat pipes, either formed in the heat sink or formed in a separated housing and attached to the heat sink. In one respect, the heat pipes transfer heat from areas of high heat generation to other areas of the heat sink to thereby spread the heat uniformly throughout the heat sink. Consequently, the heat generated by the components may be dissipated over a larger surface area of the heat sink.

Individual heat sinks are typically employed to dissipate heat from individual heat-generating components. The heat sinks are oftentimes adhesively bonded to or otherwise mounted adjacent to a face of the individual heat-generating components. In addition, the heat sinks are typically sized to match the size of the heat-generating components to which they are attached. The individual heat sinks are usually sufficient to cool the heat-generating components in electronic systems having sufficient spacing between the heat-generating components. However, as the electronic systems have become more dense and the spacing between the heat-generating components has decreased, the ability of known heat sinks to dissipate adequate amounts of heat from the heat-generating components has diminished.

To compensate for the reduced spacing in the electronic systems, heat sinks have been developed with a greater number of relatively tall fins spaced substantially close together. In this regard, the surface area over which heat may be dissipated from the heat sinks has increased, but the airflow produced through the heat sinks has decreased due to higher impedance from the higher fin density. In other words, the aspect ratio (the height of the fins divided by the distance between the fins) for these heat sinks is relatively high, for instance, 12 or higher. Unfortunately, heat sinks having relatively high aspect ratios are associated with relatively high flow resistance and pressure drops across the heat sinks, for instance, 0.15 inches of water or greater. One result of the relatively high pressure drops across the heat sinks is that fans capable of moving large amounts of air are required to cause an adequate supply of airflow through these heat sinks.

Fans capable of supplying sufficient airflow through relatively high aspect ratio heat sinks are typically too large for use in densely packed computer systems. In addition, smaller fans that may be suitable for use in densely packed computer systems often have to operate at substantially high speeds in order to provide adequate airflow levels through the heat sinks. However, operating the smaller fans at the higher speeds require greater amounts of energy, therefore increasing the costs associated with operating the computer systems. In addition, the smaller fans operating at high speeds often generate high acoustic noise, which may be disruptive to users.

### SUMMARY OF THE INVENTION

According to an embodiment, the present invention pertains to a cooling system for an electronic system housing a heat-generating component. The cooling system generally includes a heat sink having a length and a width. The heat sink is configured to dissipate heat generated by the heat-generating component and has a base and a plurality of fins attached to the base. The plurality of fins are spaced apart from one another to have a relatively low height to width aspect ratio in the spacing between the plurality of fins. In addition, the heat-generating component has PATENT a length and a width, and at least one of the length and the width of the heat sink is substantially larger than at least one of an associated length and width of the heat-generating component.

### BRIEF DESCRIPTION OF THE DRAWINGS

Features of the present invention will become apparent to those skilled in the art from the following description with reference to the figures, in which:

FIG. 1 shows a simplified partially cut-out, perspective view of an electronic system according to an embodiment of the invention;

FIG. 2 illustrates a cross-sectional, front elevational view of the electronic system shown in FIG. 1, according to an embodiment of the invention;

FIG. 3 is a partially exploded, perspective view of an electronic system according to an embodiment of the invention;

FIG. 4A is a cross-sectional front view of an electronic system according to another embodiment of the invention; and

FIG. 4B is a cross-sectional front view of an electronic system according to another embodiment of the invention.

### DETAILED DESCRIPTION OF THE INVENTION

For simplicity and illustrative purposes, the present invention is described by referring mainly to an exemplary embodiment thereof In the following description, numerous specific details are set forth in order to provide a thorough understanding of the present invention. It will be apparent however, to one of ordinary skill in the art, that the present invention may be practiced without limitation to these specific details. In other instances, well known methods and structures have not been described in detail so as not to unnecessarily obscure the present invention.

A cooling system for relatively densely packed electronic systems, for instance, computers, servers, receivers, image projectors, etc., substantially optimizes the limited available space in the electronic systems. The cooling system generally includes a heat sink designed to conduct heat from one or more heat-generating components. The heat sink comprises a footprint that is substantially larger than the footprints of the one or more heat-generating components.

The heat sink also has fins attached to a base. The fins are configured with a relatively low aspect ratio (the height of the fins divided by the distance between the fins) to thereby reduce the pressure drop across the heat sink. In one regard, air may flow between the fins with relatively low resistance, such that, relatively small, low-capacity fans may be employed to move adequate amounts of air through the fins to dissipate heat from the heat-generating components. Consequently, the amount of space required by the fans as well as the costs associated with operating the fans may be substantially reduced in comparison to known cooling systems.

In one example, the base of the heat sink includes one or more heat pipes to generally spread heat from one or more locations of the heat sink to other locations in the heat sink to thereby create a substantially isothermal surface on the heat sink. In this regard, heat conducted from the one or more heat-generating components may be dissipated over a larger surface area of the heat sink to increase heat removal capabilities from the one or more heat-generating components. A thermally conductive material may also be provided as an interface between the base of the heat sink and the one or more heat-generating components to also increase heat conduction from the one or more heat-generating components to the heat sink.

The heat sink may also include a roll bond panel having a fluid with a low boiling temperature, for example, water at reduced pressure, fluorinert, etc. In addition, or alternatively, the heat sink may comprise a panel constructed of a metallic base having chambers or openings created therein, for instance, through extrusion, casting, thixomolded magnesium, etc. The heat sink may also include a vapor chamber, for example, copper containing water at a reduced pressure, cast aluminum containing a fluid with a low boiling point temperature, for instance, FC-72, R-134a, etc.

In another example, the cooling system may be designed to include various configurations to substantially maximize the spaces available in the electronic systems. More particularly, the heat sink of the cooling system may be designed in conjunction with the components contained in the electronic systems such that the heat sink comprises a shape designed to occupy substantially PATENT all of the spaces available in the electronic systems. Alternatively, the electronic systems may be designed in conjunction with the heat sink such that the components contained in the electronic systems are arranged to accommodate the configuration of the heat sink. In any regard, the surface area available for dissipation of heat produced by the heat-generating components may be significantly increased over known cooling systems. Moreover, heat sinks having relatively lower aspect ratios may be employed to thereby reduce the pressure drop level across the electronic component.

In yet another example, the cooling system may be fabricated as part of the housing for the electronic systems. For instance, the heat sink of the cooling system may be substantially integrally fabricated with a top section of the electronic systems. In one regard, the heat sink may be designed such that the heat sink contacts one or more heat-generating components contained in the electronic component as the top section of the electronic systems are mated with the remaining sections of the electronic systems. In addition, some or all of the heat-generating components may be attached to the heat sink such that these heat-generating components may be positioned in the electronic systems as the top section is attached to a bottom section of the electronic systems.

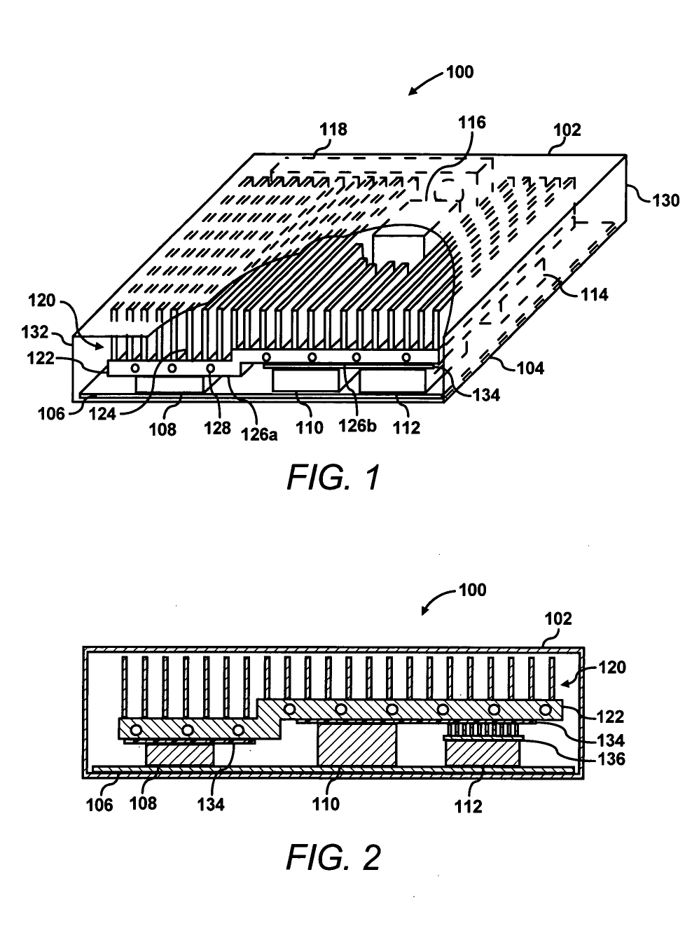

With reference now to the drawings and particularly to FIG. 1, there is shown a simplified partially cut-out, perspective view of an electronic system 100 according to an embodiment of the invention. The electronic system 100 depicted in FIG. 1 represents a generalized illustration. Therefore, other components and design features may be added or existing components or design features may be removed or modified without departing from the scope of the invention. For example, the electronic system 100 may include various openings for venting air through an interior of the electronic system 100. The electronic system 100 may also include various other components in addition to those illustrated in FIG. 1.

The electronic system 100 may comprise any system that houses heat-generating components. The electronic system 100 may therefore comprise, for instance, a computer, a server, a server mountable on a rack, a stereo receiver, etc. The electronic system 100 includes a housing 102 which may contain similar features to housings for electronic systems known in the art. A front section of the housing 102 has been omitted from the electronic system 100 in order to more clearly illustrate an interior of the electronic system 100. It should, however, be understood that the housing 102 includes a front section for both aesthetic and functional purposes.

Supported on a bottom section 104 of the housing 102 is a mounting board 106. The mounting board 106 may comprise a circuit board supporting a plurality of components, for instance, microprocessors, integrated circuits, and the like. A plurality of components 108-116 is illustrated in FIG. 1 as being mounted on the mounting board 106. It should be understood that one or more of the components 108-116 may be supported directly on the bottom section 104 or on some other mounting device other than the mounting board 106 without departing from the scope of the invention. The components 108-116 may comprise heat-generating components, for instance, microprocessors, disk drives, memory controllers, power supplies, power converters, and other components known to generate heat within electronic systems.

A cooling system 120 is provided adjacent to surfaces of the components 108-114 to conduct heat away from the components 108-114 and to dissipate the conducted heat. The cooling system 120 is generally configured to optimize the space available in the housing 102 to dissipate heat generated by the heat-generating components 108-114. The cooling system 120 comprises a heat sink having a base 122 with a plurality of fins 124 extending therefrom. The fins 124 are generally sized and spaced from one another such that they have a relatively low aspect ratio (the height of the fins 124 divided by the distance between the fins 124). For instance, the aspect ratio of the fins 124 is between approximately 6 and 9. In addition, the fins 124 are designed such that a pressure drop from one side of the cooling system 120 to the other side of the cooling system 120 is between approximately 0.03 and 0.09 inches of water. In one respect, the low aspect ratio of the fins 124 may be implemented to sufficiently cool the heat-generating components 108-114 by virtue of the space occupied by the cooling system 120. More particularly, because the heat received by the cooling system 120 may be spread over a relatively larger area as compared with known cooling systems, the low aspect ratio fins 124 generally enables adequate heat dissipation to maintain the heat-generating components 108-114 within desired temperature levels.

As illustrated in FIG. 1, the cooling system 120 is generally designed to accommodate for variously sized components 108-116. For instance, the base 122 includes sections 126a and 126b having various heights such that the base 122 may be positioned adjacent components 108-114 having different heights. Although the cooling system 120 is illustrated as having two sections 126a and 126b, the cooling system 120 may comprise any number of sections having any number of various heights to contact components having any number of various heights.

In addition, the extension of the base 122 and the fins 124 into the electronic system 100 may also vary to accommodate for components contained in the electronic system 100. For instance, as shown in FIG. 1, the base 122 and the fins 124 include portions having relatively shorter extensions into an interior of the housing 102. The space created in the base 122 and the fins 124 generally enables placement of components, for instance, the component 116. Although not explicitly shown in FIG. 1, spaces in the base 122 and the fins 124 may also be included to generally enable placement of devices in the electronic system 100 that may not generate sufficient heat for dissipation by the cooling system 120. In addition, the cooling system 120 may comprise separate elements spaced apart from one another to generally enable the placement of these devices and to utilize substantially all of the available space within the housing 102 to dissipate heat generated by the heat-generating components 108-114.

The spaces in the base 122 and the fins 124 may also be provided to enable the inclusion of one or more fans 118. The one or more fans 118 may be provided to enhance heat dissipation from the fins 124 by creating greater airflow around the fins 124 and by blowing heated air out of the housing 102. In addition, the one or more fans 118 may comprise relatively low capacity fans or high capacity fans operated at relatively low speeds to thereby enable greater airflow through the fins 124 while producing relatively low acoustic noise. The one or more fans 118 may have relatively low operating capacities due to, for instance, the relatively low pressure drop across the cooling system 120. The one or more fans 118 may be unnecessary, for instance, in situations where the cooling system 120 is configured to dissipate heat from relatively low power systems because the relatively low aspect ratio of the fins 124 generally provides a greater free convection environment. Examples of relatively low power systems may include power converters, memory controllers, etc.

Although the use of fans to increase circulation within the housing 102 is generally optional according to embodiments of the invention, fans having relatively lower capacity as compared with fans employed in known cooling systems may be utilized with examples of the invention. In one regard, the fans may be relatively smaller and/or have lower outputs due to the relatively low aspect ratio of the fins 1.24 and the reduced pressure drop across the cooling system 120.

In an example of the cooling system 120, the base 122 includes a plurality of heat pipes 128. The heat pipes 128 may comprise any reasonably suitable, commercially available heat pipes, for instance, heat pipes available from THERMACORE of Lancaster, Pa., or from FUJIKURA, of Japan. The heat pipes 128 generally operate to transfer heat received at various locations of the base 122 to other areas of the base 122. In this respect, the heat pipes 128 may spread out the received heat to thereby create a substantially isothermal distribution of heat throughout the base 122. Through spreading of the heat to various areas of the base 122, heat may be dissipated over a relatively larger number of fins 124, and therefore over a relatively larger surface area.

Although the heat pipes 128 are illustrated as extending in a direction from a front of the housing 102 to a rear of the housing 102, the heat pipes 128 may be arranged in any reasonably suitable orientation without departing from the scope of the invention. For instance, some or all of the heat pipes 128 may extend from one side section 130 to the other side section 132 of the housing 102. In addition, the heat pipes 128 may be arranged in a generally serpentine configuration and may therefore extend in various directions.

In addition or alternatively, the base 122 may comprise a roll bond panel, for instance, a panel that is defined by a fluid channel in the form of a closed labyrinth containing a working fluid. A suitable working fluid may comprise, e.g., water at reduced pressure, 3M FLOURINERT, hydrofluoroether, alcohol, etc. Suitable roll bond panels may be obtained from, for instance, Showa Aluminum Corporation, of Tokyo, Japan. In this example, heat generated by the heat-generating components 108-114 may be absorbed, for instance, by evaporation, by the working fluid contained in the base 122 and distributed throughout the labyrinth of the base 122 to heat the base 122 to a substantially uniform temperature. The distributed heat may then be dissipated through the fins 124 to thereby cool the heat-generating components 108-114.

In another embodiment, the base 122 may comprise a panel constructed of a metallic base having chambers or openings created therein, for instance, through extrusion, casting, thixomolded magnesium, etc. The base 122 may include heat pipes that are integrated into the base 122. For instance, the base 122 may include a vapor chamber, for instance, copper containing water at a reduced pressure, cast aluminum containing a fluid with a low boiling point temperature, e.g., FC-72, R-134a, etc. Again, heat generated by the heat-generating components 108-114 may be absorbed by the working fluid contained in the vapor chamber and distributed throughout the base 122. The distributed heat may be dissipated through a number of fins 124 positioned at various locations on the base 122 to thereby cool the heat-generating components 108-114.

Also shown in FIG. 1, is an optional interface material 134 positioned between the heat-generating components 110 and 112 and the second section 126b of the base 122. The interface material 134 generally comprises any reasonably suitable material designed to enhance thermal conduction between the heat-generating components 110 and 112 and the base 122. The interface material 134 may also accommodate for possible irregularities in the surfaces between the heat-generating components 110 and 112 and the base 122. Interface materials suitable for use with embodiments of the invention are available from, for instance, The Bergquist Company of Chanhassen, Minn. The interface material 134 may comprise a relatively thin strip of material and may have varying thicknesses. For instance, the interface material 134 may be thinner at locations of relatively high power components, for instance, microprocessors, etc., than locations of relatively low power components, for instance, memory controllers, power converters, etc. For example, the interface material 134 may comprise a thickness of around 0.001 to 0.003 inches at locations of the relatively high power components and a thickness of around 0.010 to 0.030 inches at locations of the relatively low power components. In addition, the thickness of the interface material 134 may vary to accommodate for irregularilities in the heights of the components 108-114.

Although the interface material 134 is illustrated as being positioned between the heat-generating components 110 and 112 and the base 122, interface material 134 may be provided at any reasonably suitable location where heat is to be conducted from one component to another without departing from the scope of the invention. For instance, the interface material 134 may also be provided between the heat-generating components 108 and 114 and the base 122.

FIG. 2 illustrates a cross-sectional, front elevational view of the electronic system 100 shown in FIG. 1, according to an embodiment of the invention. As illustrated in FIG. 2, the electronic system 100 includes a housing 102 and a mounting board 106. Positioned on the mounting board 106 are heat-generating components 108-112. The heat-generating components 108-112 each comprise a different height and the cooling system 120 is generally configured to receive heat from the heat-generating components 108-112 by accommodating for the various heights of the heat-generating components 108-112. As shown in FIG. 2, the cooling system 120 includes various heights to allow for sufficient space below the cooling system 120 for the variously sized heat-generating components 108-112 while maintaining thermal contact with the heat-generating components 108-112.

As described hereinabove, interface material 134 may be positioned between the cooling system 120 and the heat-generating components 108-112 to enhance thermal conduction therebetween. The interface material 134 may comprise a relatively resilient and deformable material to enable relatively effective thermal contact with the heat-generating components 108-112 by accommodating for possible irregularities in the surfaces between the heat-generating components 108-112 and the base 122 of the cooling system 120. For instance, the interface material 134 may enable a relatively effective thermal connection when the heat-generating component 112 includes a heat sink 136. In this instance, heat generated by the heat-generating component 112 is conducted through the heat sink 136 and the interface material 134 to the cooling system 122.

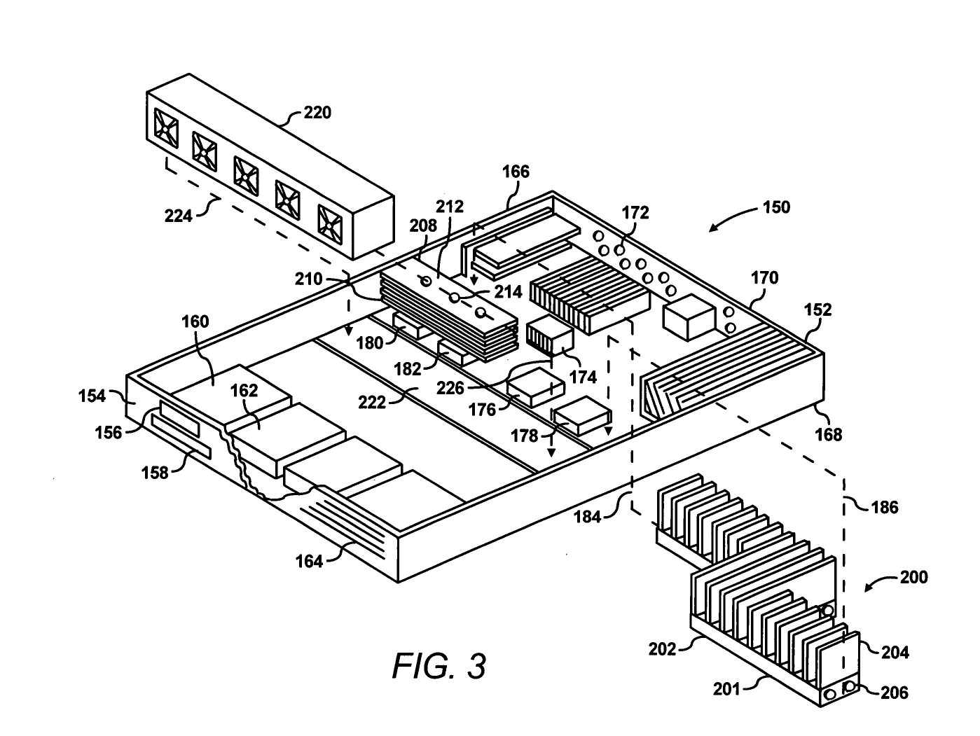

FIG. 3 is a partially exploded, perspective view of an electronic system 150 according to an embodiment of the invention. The electronic system 150 depicted in FIG. 3 comprises a server configured for mounting in a rack (not shown). The electronic system 150 represents a generalized illustration and, therefore, other components and design features may be added or existing components or design features may be removed or modified without departing from the scope of the invention. For example, the electronic system 150 may include various openings for venting air through an interior of the electronic system 150.

The electronic system 150 includes a housing 152 with a top section of the housing 152 being removed for purposes of illustration. In addition, a part of a front section 154 of the housing 152 has been cut-away to more clearly show some of the components contained in the electronic system 150. The front section 154 is illustrated as containing various features to enable access to components mounted in the electronic system 150. For instance, the front section 154 includes openings 156 and 158 for insertion of various media, for example, diskettes, flash memory cards, CD-Roms, etc. Located substantially directly behind the openings 156 and 158 are data storage devices 160 and 162 configured to read and/or write onto the various media. The front section 154 also includes vents 164 for enabling airflow into the housing 152.

The housing 152 also includes a plurality of side sections 166 and 168 and a rear section 170. The rear section 170 includes openings 172 to generally enable airflow out of the housing 152. Although not clearly shown in FIG. 3, the rear section 170 also includes openings for insertion of wires, cables, and the like into the housing 152 for connection to various components contained in the housing 152. In addition, some of the openings 172 in the rear section 170 may include devices to enable interfacing of certain components contained in the housing 152.

Contained within the housing 152 are a plurality of heat-generating components 174-182. Some of the heat-generating components 174-182 may comprise microprocessors, power converters, memory controllers, power supplies, disk drives, etc. It should be readily appreciated that the electronic system 150 depicted in FIG. 3 represents a generalized illustration and that other components and design features may be added or existing components or design features may be removed or modified without departing from the scope of the invention. For example, the housing 152 may include various other openings for venting air through an interior of the housing 152 and various devices for mating the electronic system 150 to a rack. The electronic system 150 may also include various other components in addition to those illustrated in FIG. 3.

A cooling system 200 is also illustrated in FIG. 3. The cooling system 200 includes a first heat sink 201 having a similar construction to the cooling system 120 illustrated in FIGS. I and 2 and therefore a relatively detailed description of the first heat sink 201 is omitted. Instead, the disclosure cited hereinabove pertaining to the cooling system 120 is relied upon as providing adequate disclosure of the various elements and examples of the first heat sink 201.

The first heat sink 201 comprises a base 202 and a plurality of fins 204. Extending through the base 202 is a pair of heat pipes 206. Alternatively, the base 202 may comprise any of the configurations described hereinabove with respect to the cooling system 120. The first heat sink 201 is also illustrated as having a configuration which enables the first heat sink 201 to occupy available spaces in the housing 152. In addition, the configuration of the first heat sink 201 generally enables the cooling system 200 to thermally contact surfaces of a plurality of heat-generating components 174-182. In this regard, the first heat sink 201 may be inserted into the housing 152 as indicated by the arrows 184 and 186.

The configuration of the first heat sink 201 depicted in FIG. 3 is for illustration purposes and is not intended to limit the invention in any respect. Instead, the first heat sink 201 may comprise any reasonably suitable configuration configured to-enable heat conduction from the heat-generating components 174-182 and dissipated by the first heat sink 201, while maintaining the aspect ratio of the fins 204 at a relatively low level.

According to an example of the electronic system 150, the cooling system 200 includes a second heat sink 208, which is illustrated as forming a separate component from the first heat sink 201. The second heat sink 208 generally includes a base 210 and fins 212. The fins 212 of the second heat sink 208 are horizontally arranged and include heat pipes 214 extending vertically through the fins 212. The heat pipes 214 generally operate to conduct heat from the base 210 through the fins 212, where the heat may be dissipated, for instance, through convection with air flowing between the fins 212.

The fins 212 are arranged such that they have spaced relatively far apart from each other. For instance, the fins 212 maybe spaced around 0.106 inch to 0.2 inch spacing. In addition, the fins 124 are designed such that a pressure drop from one side of the second heat sink 208 to the other side of the second heat sink 208 is between approximately 0.03 and 0.09 inches of water.

In one respect, the low aspect ratio of the fins 212 may be implemented to sufficiently cool the heat-generating components, for instance, components 180 and 182, by virtue of the space occupied by the second heat sink 208. More particularly, because the heat received by the second heat sink 208 may be spread over a relatively larger area as compared with known cooling systems, the spacing between the fins 212 generally enables adequate heat dissipation to maintain the heat-generating components 180 and 182 within desired temperature levels.

Although the second heat sink 208 has been shown as comprising a component that is separate from the first heat sink 201, the second heat sink 208 may be integrally formed with the first heat sink 201 without departing from the scope of the invention. The second heat sink 208 may also be configured for thermal contact with the first heat sink 201. In this regard, heat collected by the second heat sink 208 may be spread to the first heat sink 201. In addition, heat collected by the first heat sink 201 may be spread to the second heat sink 208. Consequently, the surface area over which heat may be dissipated from the components 174-182 may be increased.

The cooling system 200 may also include a fan cell 220 composed of fans for blowing air through the first heat sink 201 and the second heat sink 208. The fan cell 220 is depicted as containing five fans for illustrative purposes only and may therefore contain any reasonably suitable number of fans, for instance, from 1 to 10 or more fans. The fans contained in the fan cell 220 may comprise relatively low capacity fans or they may comprise high capacity fans that may be operated at low capacity levels. In addition, the fans may have sufficiently small dimensions to enable their placement in the housing 152 without, for instance, substantially interfering with the operations of other components contained in the housing 152. For instance, the fans of the fan cell 220 may be 40 mm fans which may be operated in low pressure drop conditions, for instance, around 0.03 to 0.09 inches of water. In addition, the fans of the fan cell 220 may be configured to generate airflow at around 5-10 cfin.

The fan cell 220 may be positioned in the housing 152 in a fan mount 222 as indicated by the arrows 224 and 226. As shown in FIG. 3, the fan cell 220 may be positioned in the housing 152 to enhance airflow through the cooling system 200. More particularly, the fan cell 220 is positioned to increase airflow through the first heat sink 201 and the second heat sink 208 to thereby increase heat dissipation through convection from the fins 204 and 212 of the first heat sink 201 and the second heat sink 208.

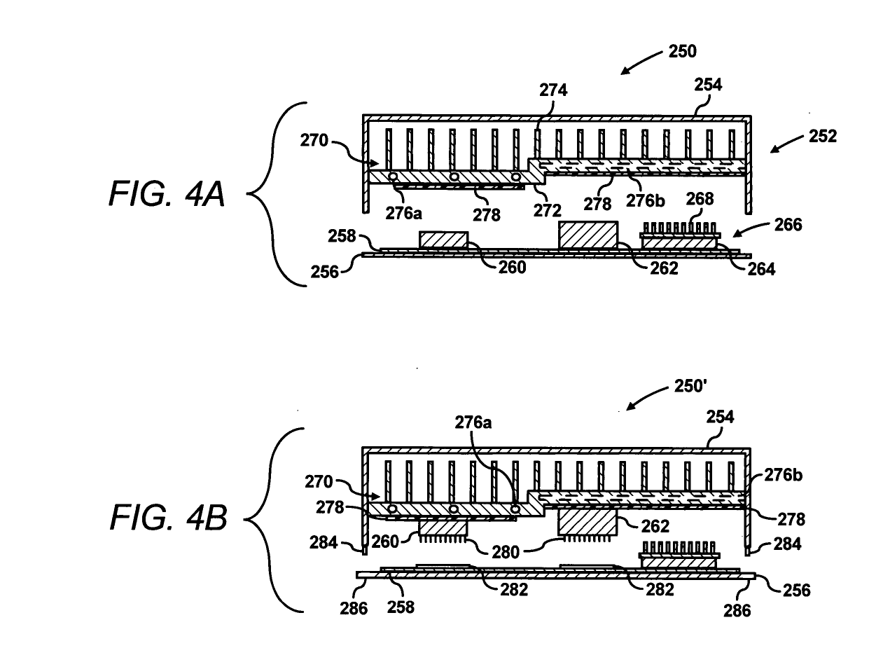

FIG. 4A is a cross-sectional front view of an electronic system 250 according to another embodiment of the invention. The electronic system 250 may comprise a computer system or server configured for mounting in a rack (not shown). In addition, the electronic system 250 represents a generalized illustration and, therefore, other components and design features may be added or existing components or design features may be removed or modified without departing from the scope of the invention. For example, the electronic system 150 may include various openings for venting air through an interior of the electronic system 150. Moreover, the electronic system 250 may include components known to be contained in computer systems or servers in addition to those described hereinbelow with respect to FIG. 4A.

The electronic system 250 includes a housing 252 having a top section 254 and a bottom section 256. A front section and a rear section of the housing 252 are not shown in FIG. 4A to enable a clearer illustration of the interior of electronic system 250. The front and rear section may be formed separately from either the top section 254 or the bottom section 256. Alternatively, either of the front section and the rear section may be formed as part of either the top section 254 or the bottom section 256. In any regard, the housing 252 may form an enclosure around the components contained in the electronic system 250.

Located on the bottom section 256 of the housing 252 is a mounting board 258. The mounting board 258 may comprise a circuit board supporting a plurality of components, for instance, microprocessors, integrated circuits, and the like. A plurality of components 260-264 is illustrated in FIG. 4A as being mounted on the mounting board 258. It should be understood that one or more of the components 260-264 may be supported directly on the bottom section 256 or on some other mounting device other than the mounting board 258 without departing from the scope of the invention. The components 260-264 may comprise heat-generating components, for instance, microprocessors, disk drives, memory controllers, power supplies, power converters, and other components known to generate heat within electronic systems, for instance, computers, servers, and the like.

The component 264 is illustrated as containing a heat sink 266 having a plurality of fins 268 configured to dissipate heat collected from the component 264. It should be understood, however, that any or all of the components 260-264 may include separate heat sinks or that none of the components 260-264 includes separate heat sinks without departing from the scope of the invention.

The electronic system 250 includes a cooling system 270 having a base 272 and fins 274 extending from the base 272. The cooling system 270 generally includes a similar configuration to, for instance, the cooling system 120 illustrated in FIGS. I and 2, and therefore a relatively detailed description of the cooling system 270 is omitted. Instead, the disclosure cited hereinabove pertaining to the cooling system 120 is relied upon as providing adequate disclosure of the various elements and examples of the cooling system 270.

Extending through the base 272 are heat pipes 276a and 276b. The heat pipes 276a are illustrated as extending into FIG. 4A and the heat pipes 276b are illustrated as extending in a lateral direction of the base 272. The heat pipes 276a and 276b may comprise any reasonably suitable, commercially available heat pipes, for instance, heat pipes available from THERMACORE of Lancaster, Pa., or from FUJIKURA, of Japan. A more detailed description of the heat pipes 276a and 276b may be found hereinabove with respect to the description of the heat pipes 128 in FIG. 1.

Although the heat pipes 276a and 276b are illustrated as extending in varying directions, the heat pipes 276a and 276b may be arranged in any reasonably suitable orientation without departing from the scope of the invention. For instance, some or all of the heat pipes 276a and 276b may extend in substantially the same direction. In addition, some or all of the heat pipes 276a and 276b may be arranged in a generally serpentine configuration and may therefore extend in various directions.

In addition or alternatively, the base 272 may comprise a roll bond panel, for instance, a panel that is defined by a fluid channel in the form of a closed labyrinth containing a working fluid. A suitable working fluid may comprise, e.g., water at reduced pressure, 3M FLOURINERT, hydrofluoroether, alcohol, etc. Suitable roll bond panels may be obtained from, for instance, Showa Aluminum Corporation, of Tokyo, Japan. In this example, heat generated by the components 260-264 may be transferred by evaporation of the working fluid contained in the base 272 and distributed throughout the labyrinth of the base 272 to heat the base 272 to a substantially uniform temperature. The distributed heat may then be dissipated through the fins 274 to thereby cool the components 260-264.

According to another example, the base 272 may comprise a panel constructed of a metallic base having chambers or openings created therein, for instance, through extrusion, casting, thixomolded magnesium, etc. The base 272 may include heat pipes that are integrated into the base 272. For instance, the base 272 may include a vapor chamber, for instance, copper containing water at a reduced pressure, cast aluminum containing a fluid with a low boiling point temperature, e.g., FC-72, R-134a, etc. Again, heat generated by the components 260-264 may be absorbed by the working fluid contained in the vapor chamber and distributed throughout the base 272. The distributed heat may be dissipated through the fins 274 positioned at various locations on the base 272 to thereby dissipate the heat generated by the components 260-264.

As shown in FIG. 4A, the cooling system 270 is attached to the top section 254. More particularly, the base 272 of the cooling system 270 is depicted as being attached to inner surfaces of the top section 254. According to this example, the cooling system 270 may be attached to the top section 254 through any reasonably suitable means. For instance, the cooling system 270 may be attached to the top section 254 with welds, adhesives, mechanical fasteners, etc. In addition, part or all of the cooling system 270 may be integrally formed with the top section 254.

The cooling system 270 may be attached to the top section 254 through various other reasonably suitable means without departing from the scope of the invention. For instance, the fins 274 of the cooling system 270 may be attached to the top section 254 in any of the manners described hereinabove with respect to the attachment of the base 272 to the top section 254. As another example, brackets or other mechanical devices may be attached to the interior of the top section 254 and may be employed to support the cooling system 270.

In any regard, the cooling system 270 is configured to thermally contact the components 260-264 when the top section 254 is placed on the bottom section 256. In addition, interface material 278, for instance, interface material 134, configured to enhance thermal conduction between the components 260-264 and the cooling system 270 may be positioned at various locations along the base 272. The interface material 278 may also enable substantially enhanced thermal contact between the components 260-264 and the base 272 by accommodating for various irregularities in the contact surfaces of the components 260-264 and the base 272.

In addition, the cooling system 270 is configured to disengage from the components 260-264 when the top section 254 is disengaged from the bottom section 256. In this regard, the components 260-264 may be relatively easily accessed through removal of the top section 254.

The configuration of the cooling system 270 is for illustration purposes and is not intended to limit the invention in any respect. Instead, the cooling system 270 may comprise any reasonably suitable configuration configured to enable heat conduction from the components 260-264 and dissipated by the cooling system 270, while maintaining the aspect ratio of the fins 274 at a relatively low level.

FIG. 4B is a cross-sectional front view of an electronic system 250′ according to another embodiment of the invention. The electronic system 250′ includes all of the elements disclosed hereinabove with respect to the electronic system 250 depicted in FIG. 4A. Accordingly, only those elements that differ in the electronic system 250′ are described in substantial detail.

As depicted in FIG. 4B, the components 260 and 262 are attached to the cooling system 270. The components 260 and 262 are illustrated as being attached to the interface materials 276a and 276b. According to an example of the electronic system 250′, the components 260 and 262 may be removably attached to the interface materials 276a and 276b, for instance, through use of mechanical devices or removable adhesives. In this regard, the components 260 and 262 may be relatively easily removed and/or replaced. According to another example, the components 260 and 262 may be attached to the interface materials 276a and 276b through relatively permanent means, for instance, stronger adhesives, and the like.

The components 260 and 262 are illustrated as containing contacting pins 280. The contacting pins 280 generally comprise male connectors configured to mate with, for instance, female connectors 282 on the mounting board 258. The connection between the contacting pins 280 and the female connectors 282 generally enables communication between the components 260 and 262 and the mounting board 258. Thus, as the top section 254 is lowered onto the bottom section 256, the contacting pins 280 may be inserted into the respective female connectors 282. In addition, after assembly of the top section 254 and the bottom section 256, the connectors 260 and 262 may be decoupled from the female connectors 282 by withdrawing the top section 254 from the bottom section 256. Although the contacting pins 280 have been illustrated as extending from the components 260 and 262, it should be understood that the components 260 and 262 may include the female connectors 282 and that the contacting pins 280 may extend from the mounting board 258 without deviating from the operability of the present example.

The top section 254 is illustrated as containing male connectors 284 configured for insertion into openings 286 in the bottom section 256. The male connectors 284 and the openings 286 generally operate to removably connect the top section 254 to the bottom section 256. In addition, the male connectors 284 may operate as guides during the insertion of the contacting pins 280 into the female connectors 282. In one regard, the male connectors 284 may operate to generally protect the contacting pins 280 as they are inserted into the female connectors 282 by substantially absorbing lateral stresses that may be applied during mating of the top section 254 to the bottom section 256.

In one regard, according to this example, the amount of time required to position the components 260 and 262 may be substantially reduced as they may substantially automatically be positioned during connection of the top section 254 to the bottom section 256.

What has been described and illustrated herein is a preferred embodiment of the invention along with some of its variations. The terms, descriptions and figures used herein are set forth by way of illustration only and are not meant as limitations. Those skilled in the art will recognize that many variations are possible within the spirit and scope of the invention, which is intended to be defined by the following claims—and their equivalents—in which all terms are meant in their broadest reasonable sense unless otherwise indicated.

1. A cooling system for an electronic system housing a heat-generating component, said cooling system comprising:
a heat sink having a length and a width, the heat sink including:
a base;
a plurality of fins attached to the base, wherein the plurality of fins are spaced apart from one another to have a relatively low height to width aspect ratio in the spacing between the plurality of fins; and
wherein the heat-generating component has a length and a width, and wherein at least one of the length and the width of the heat sink is substantially larger than at least one of an associated length and width of the heat-generating component, said heat sink being configured to dissipate heat generated by the heat-generating component.

2. The cooling system according to claim 1, wherein the aspect ratio is between approximately 6 and 9.

3. The cooling system according to claim 1, wherein the heat sink includes a first side and a second side and wherein a pressure drop from the first side to the second side of the heat sink is between approximately 0.03 and 0.09 inches of water.

4. The cooling system according to claim 1, further comprising:
one or more heat pipes extending through at least a portion of the base.

5. The cooling system according to claim 1, wherein the base comprises a fluid channel in the form of a closed labyrinth containing a working fluid having a relatively low boiling point temperature.

6. The cooling system according to claim 1, wherein the base comprises a vapor chamber containing a working fluid having a relatively low boiling point temperature.

7. The cooling system according to claim 1, further comprising:
a heat conductive interface material for placement between the heat sink and the heat-generating component.

8. The cooling system according to claim 1, further comprising:
one or more fans configured to blow air through the plurality of fins, wherein the one or more fans comprise relatively low capacity fans.

9. The cooling system according to claim 1, further comprising a plurality of heat sinks, at least one of the plurality of heat sinks having a different configuration from at least one other heat sink of the plurality of heat sinks.

10. The cooling system according to claim 1, wherein the electronic system comprises a plurality of heat-generating components, at least one of the plurality of heat-generating components having a different height from at least one other of the plurality of heat-generating components, wherein the base comprises sections having various heights to substantially accommodate for the different heights of the plurality of heat-generating components.

11. An electronic system having a heat-generating component, said electronic system comprising:
a housing having a first section and a second section, wherein the first section is attachable to the second section; and
a cooling system having a base and a plurality of fins configured to dissipate heat generated by the heat-generating component attached to the first section, said cooling system being configured to contact the heat-generating component when the first section is attached to the second section.

12. The system according to claim 11, wherein said housing includes a relatively open space around the heat-generating component and wherein the cooling system occupies substantially all of the relatively open space around the heat-generating component.

13. The system according to claim 11, wherein the plurality of fins are configured to have a relatively low height to width aspect ratio.

14. The system according to claim 13, wherein the aspect ratio is between approximately 6 and 9.

15. The system according to claim 11, wherein the cooling system includes a first side and a second side and wherein a pressure drop from the first side to the second side of the cooling system is between approximately 0.03 and 0.09 inches of water.

16. The system according to claim 11, wherein the cooling system includes one or more heat pipes extending through at least a portion of the base.

17. The system according to claim 11, a heat conductive interface material placed between the base and the heat-generating component.

18. The system according to claim 11, wherein the cooling system includes one or more fans configured to blow air through the plurality of fins, wherein the one or more fans comprise relatively low capacity fans.

19. The system according to claim 11, wherein the cooling system comprises a plurality of heat sinks, at least one of the plurality of heat sinks having a different configuration from at least one other heat sink of the plurality of heat sinks.

20. An electronic system having a heat-generating component, said electronic system comprising:
a housing having a first section and a second section, wherein the first section is attachable to the second section; and
a cooling system configured to dissipate heat generated by the heat-generating component attached to the first section, said heat-generating component being thermally attached to the cooling system, wherein the heat-generating component is configured to become positioned in the electronic system when the first section is attached to the second section.

21. The system according to claim 20, further comprising:
a mounting board, wherein the heat-generating component is configured to engage the mounting board when the first section is attached to the second section.

22. The system according to claim 21, wherein the heat-generating component comprises engaging elements for engaging the mounting board.

23. The system according to claim 22, wherein the first section comprises a first mating device and the second section comprises a second mating device, wherein the first mating device is configured to engage the second mating device when the first section is attached to the second section, and wherein the engagement between the first mating device and the second mating device is configured to substantially protect the engaging elements of the heat-generating component.

24. The system according to claim 20, wherein said housing includes a relatively open space around the heat-generating component and wherein the cooling system occupies substantially all of the relatively open space around the heat-generating component.

25. The system according to claim 20, wherein the cooling system comprises a base and a plurality of fins configured to dissipate heat generated by the heat-generating component, said plurality of fins being configured to have a relatively low height to width aspect ratio.

26. The system according to claim 25, wherein the aspect ratio is between approximately 6 and 9.

27. The system according to claim 25, wherein the cooling system includes a first side and a second side and wherein a pressure drop from the first side to the second side of the cooling system is between approximately 0.03 and 0.09 inches of water.

28. The system according to claim 25, wherein the cooling system includes one or more heat pipes extending through at least a portion of the base.

29. The system according to claim 25, a heat conductive interface material placed between the base and the heat-generating component.

30. The system according to claim 20, wherein the cooling system includes one or more fans configured to blow air through the plurality of fins, wherein the one or more fans comprise relatively low capacity fans.

31. The system according to claim 20, wherein the cooling system comprises a plurality of heat sinks, at least one of the plurality of heat sinks having a different configuration from at least one other heat sink of the plurality of heat sinks.

32. A method of dissipating heat generated by a heat-generating component in an electronic system having available space, said method comprising:
thermally contacting a cooling system that occupies a substantial portion of the available space in the electronic system to the heat-generating component, said cooling system also including fins having a relatively low height to width aspect ratio;
conducting heat generated by the heat-generating component to the cooling system; and
dissipating the heat conducted from the heat-generating component to cool the heat-generating component.

33. The method according to claim 32, wherein the electronic system includes a housing having a first section and a second section, wherein the first section is attachable to the second section, said method further comprising:
attaching the cooling system to the first section prior to the step of thermally contacting the cooling system to the heat-generating component; and
wherein the step of thermally contacting the cooling system to the heat-generating component comprises attaching the first section to the second section.

34. The method according to claim 32, wherein the electronic system includes a housing having a first section and a second section, wherein the first section is attachable to the second section, and wherein the second section includes a mounting board, said method further comprising:
attaching the cooling system to the first section prior to the step of thermally contacting the cooling system to the heat-generating component;
wherein the step of thermally contacting the cooling system to the heat-generating component comprises attaching the heat-generating component to the cooling system; and
engaging the heat-generating component with the mounting board during attachment of the first section to the second section.

35. A system for dissipating heat generated by a heat-generating component in an electronic system having available space, said system comprising:
means for thermally contacting a cooling system that occupies a substantial portion of the available space in the electronic system to the heat-generating component, said cooling system having fins with a relatively low height to width aspect ratio;
means for conducting heat by the heat-generating component to the cooling system; and
means for dissipating the heat conducted from the heat-generating component, to thereby cool the heat-generating component.

36. The system according to claim 35, wherein the electronic system includes a housing having a first section and a second section, wherein the first section is attachable to the second section, said system further comprising:
means for attaching the cooling system to the first section; and
means for engaging the first section to the second section, wherein the means for thermally contacting the cooling system to the heat-generating component is operable to contact the cooling system to the heat-generating component through engagement of the first section to the second section by the means for engaging.

37. The system according to claim 35, wherein the electronic system includes a housing having a first section and a second section, wherein the first section is attachable to the second section, and wherein the second section includes a mounting board, said system further comprising:
means for attaching the cooling system to the first section;
means for attaching the heat-generating component to the cooling system;
means for engaging the first section to the second section; and
means for engaging the heat-generating component with the mounting board through engagement of the first section to the second section by the means for engaging the first section to the second section.
